(19) United States
(12) Patent Application Publication
(10) Pub. No.: US 2025/0062061 A1
(43) Pub. Date: Feb. 20, 2025

(54) COIL DEVICE AND PRINTED WIRING BOARD

(71) Applicants: SUMITOMO ELECTRIC PRINTED CIRCUITS, INC., Shiga (JP); SUMITOMO ELECTRIC INDUSTRIES, LTD., Osaka (JP)

(72) Inventors: Michi OGATA, Shiga (JP); Takeshi HAMADA, Shiga (JP); Kou NOGUCHI, Shiga (JP); Koji NITTA, Osaka (JP); Shoichiro SAKAI, Osaka (JP); Yukie TSUDA, Osaka (JP)

(73) Assignees: SUMITOMO ELECTRIC PRINTED CIRCUITS, INC., Shiga (JP); SUMITOMO ELECTRIC INDUSTRIES, LTD., Osaka (JP)

(21) Appl. No.: 18/723,532

(22) PCT Filed: Dec. 22, 2022
(86) PCT No.: PCT/JP2022/047444

§ 371 Date: Jun. 24, 2024

(30) Foreign Application Priority Data
Jan. 5, 2022 (JP) 2022-000510
Feb. 14, 2022 (JP) 2022-020718

(51) Int. Cl. H01F 17/00; H01F 41/04; H05K 1/14; H05K 1/16

(52) U.S. Cl. CPC H01F 17/0013; H01F 41/043; H05K 1/144; H05K 1/165; H05K 2201/041; H05K 2201/0776; H05K 2201/09263; H05K 2201/09281; H05K 2201/09454

(57) ABSTRACT

The coil device includes a plurality of printed wiring boards and an adhesive layer. The plurality of printed wiring boards are stacked in a thickness direction of the coil device. Each of the plurality of printed wiring boards includes a base film having a first main surface and a second main surface, and a coil wire formed in a spiral shape on at least one of the first main surface and the second main surface. The adhesive layer is disposed between the plurality of printed wiring boards adjacent to each other in the thickness direction of the coil device. The coil device has a portion that satisfies expression (1).

$$0.35 \leq R 1 \times R 2 \leq 0.85 \qquad Expression ( 1 )$$

### TECHNICAL FIELD

The present disclosure relates to a coil device and a printed wiring board. The present application claims priority based on Japanese Patent Application No. 2022-510 filed on Jan. 5, 2022 and Japanese Patent Application No. 2022-020718 filed on Feb. 14, 2022. The entire contents described in the Japanese patent applications are incorporated herein by reference.

### BACKGROUND ART

For example, Japanese Patent Laying-Open No. 2016-9854 (PTL 1) discloses a printed wiring board. The printed wiring board described in PTL 1 includes a base film, a first conductive pattern, a second conductive pattern, a first adhesive layer, a first cover film, a second adhesive layer, and a second cover film.

The base film has a first main surface and a second main surface. The first conductive pattern is formed in a spiral shape on the first main surface. The second conductive pattern is formed in a spiral shape on the second main surface. The first conductive pattern and the second conductive pattern are electrically connected to each other.

The first adhesive layer is disposed on the first main surface so as to cover the first conductive pattern. The first cover film is disposed on the first adhesive layer. The second adhesive layer is disposed on the second main surface so as to cover the second conductive pattern. The second cover film is disposed on the second adhesive layer.

### CITATION LIST

### Patent Literature

PTL 1: Japanese Patent Laying-Open No. 2016-9854

### SUMMARY OF INVENTION

A coil device according to the present disclosure includes a plurality of printed wiring boards and an adhesive layer. The plurality of printed wiring boards are stacked in the thickness direction of the coil device. Each of the plurality of printed wiring boards includes a base film having a first main surface and a second main surface, and a coil wire formed in a spiral shape on at least one of the first main surface and the second main surface. The adhesive layer is disposed between the plurality of printed wiring boards adjacent to each other in the thickness direction of the coil device. The thickness of the coil device is a sum of a thickness of the adhesive layer and a sum of a thickness of the coil wire and a thickness of the base film for the plurality of printed wiring boards. The coil device has a portion that satisfies expression (1). R1 is obtained by averaging a value obtained by dividing a width of the coil wire by a pitch between two adjacent portions of the coil wire for the plurality of printed wiring boards. R2 is obtained by summing a value obtained by dividing the thickness of the coil wire by the thickness of the coil device for the plurality of printed wiring boards.

$$0.35 \leq R 1 \times R 2 \leq 0.85 \qquad Expression ( 1 )$$

### BRIEF DESCRIPTION OF DRAWINGS

FIG. 1 is a cross-sectional view of a printed wiring board 100;

FIG. 2 is a planar view of the printed wiring board 100;

FIG. 3 is a bottom view of the printed wiring board 100;

FIG. 4 is a process chart illustrating a method of manufacturing the printed wiring board 100;

FIG. 5 is a cross-sectional view illustrating a seed layer forming step S1;

FIG. 6 is a cross-sectional view illustrating a resist forming step S2;

FIG. 7 is a cross-sectional view illustrating a first electrolytic plating step S3;

FIG. 8 is a cross-sectional view illustrating a resist removing step S4;

FIG. 9 is a cross-sectional view illustrating an etching step S5;

FIG. 10 is a cross-sectional view illustrating a second electrolytic plating step S6;

FIG. 11 is a cross-sectional view of a coil device 200; and

FIG. 12 is a graph illustrating a relationship between a value obtained by multiplying ratio R1 by ratio R2 and performance of each sample.

### DETAILED DESCRIPTION

### Problem to be Solved by the Present Disclosure

Since the pattern density of the first conductive pattern and the pattern density of the second conductive pattern can be increased as the pitch between the adjacent portions of the first conductive pattern and the pitch between the adjacent portions of the second conductive pattern decrease, it is possible to improve the thrust generated by the coil device using the printed wiring board described in PTL 1.

Further, since the electrical resistance of the first conductive pattern per unit length and the electrical resistance of the second conductive pattern per unit length decrease as the thickness of the first conductive pattern and the thickness of the second conductive pattern increase, it is possible to prevent the electrical resistance of the entire first conductive pattern and the electrical resistance of the entire second conductive pattern from increasing even if the pattern density of the first conductive pattern and the pattern density of the second conductive pattern are increased.

However, according to the printed wiring board described in PTL 1, it is difficult to make smaller the pitch of the first conductive pattern and the second conductive pattern while making thicker the first conductive pattern and the second conductive pattern. Therefore, the printed wiring board described in PTL 1 has a room for improvement in thrust and electrical resistance when the printed wiring board is used in a coil device.

The present disclosure has been made in view of the problems of the prior art mentioned above. More specifically, the present disclosure provides a coil device with improved thrust and electrical resistance.

### Advantageous Effect of the Present Disclosure

According to the coil device of the present disclosure, it is possible to improve the thrust and electrical resistance.

### DESCRIPTION OF EMBODIMENTS

First, embodiments of the present disclosure will be described.

(1) The coil device according to an embodiment includes a plurality of printed wiring boards and an adhesive layer. The plurality of printed wiring boards are stacked in the thickness direction of the coil device. Each of the plurality of printed wiring boards includes a base film having a first main surface and a second main surface, and a coil wire formed in a spiral shape on at least one of the first main surface and the second main surface. The adhesive layer is disposed between the plurality of printed wiring boards adjacent to each other in the thickness direction of the coil device. The thickness of the coil device is a sum of a thickness of the adhesive layer and a sum of a thickness of the coil wire and a thickness of the base film for the plurality of printed wiring boards. The coil device has a portion that satisfies expression (1). R1 is obtained by averaging a value obtained by dividing a width of the coil wire by a pitch between two adjacent portions of the coil wire for the plurality of printed wiring boards. R2 is obtained by summing a value obtained by dividing the thickness of the coil wire by the thickness of the coil device for the plurality of printed wiring boards.

$$0.35 \leq R 1 \times R 2 \leq 0.85 \qquad Expression ( 1 )$$

According to the coil device described in (1), it is possible to improve the thrust and electrical resistance.

(2) A printed wiring board according to an embodiment includes a base film having a first main surface and a second main surface, and a coil wire formed in a spiral shape on the first main surface and the second main surface. The printed wiring board has a portion that satisfies expression (2). R3 is obtained by dividing a width of the coil wire by a pitch between two adjacent portions of the coil wire. R4 is a ratio of a thickness of the coil wire on the first main surface and the second main surface to a distance between an upper surface of the coil wire on the first main surface and an upper surface of the coil wire on the second main surface.

$$0.35 \leq R 3 \times R 4 \leq 0.85 \qquad Expression ( 2 )$$

According to the printed wiring board described in (2), it is possible to improve the thrust and electrical resistance when the printed wiring board is used in a coil device.

(3) A printed wiring board according to another embodiment includes a base film having a first main surface and a second main surface, a coil wire formed in a spiral shape on the first main surface and the second main surface, and a protective layer disposed on the first main surface and the second main surface so as to cover the coil wires. The printed wiring board has a portion that satisfies expression (3). R3 is obtained by dividing a width of the coil wire by a pitch between two adjacent portions of the coil wire. R5 is a ratio of a thickness of the coil wire on the first main surface and the second main surface to a thickness of the printed wiring board.

$$0.30 \leq R 3 \times R 5 \leq 0.9 \qquad Expression ( 3 )$$

According to the printed wiring board described in (3), it is possible to improve the thrust and electrical resistance when the printed wiring board is used in a coil device.

(4) The printed wiring board described in (3) may have a portion that satisfies expression (4).

$$0.40 \leq R 3 \times R 5 \leq 0.65 \qquad Expression ( 4 )$$

According to the printed wiring board described in (4), it is possible to further improve the thrust and electrical resistance when the printed wiring board is used in a coil device.

(5) In the printed wiring board described in (3) or (4), the protective layer may have an adhesive layer covering the coil wire. The thickness of the adhesive layer may be 10 μm or more and 25 μm or less.

According to the printed wiring board described in (5), it is possible to prevent air bubbles from being mixed into the adhesive layer.

(6) In the printed wiring board described in any one of (2) to (5), the coil wire may have a portion that satisfies expression (5). W is a width of the coil wire. P is a pitch between two adjacent portions of the coil wire.

$$0.72 \leq W \div P \leq 0.93 \qquad Expression ( 5 )$$

(7) In the printed wiring board described in any one of (2) to (6), the coil wire may have a portion where the thickness thereof is 40 μm or more and 60 μm or less.

(8) In the printed wiring board described in any one of (2) to (7), the coil wire may have a portion where the width thereof is 20 μm or more and 40 μm or less.

### DETAILS OF EMBODIMENTS OF THE PRESENT DISCLOSURE

Hereinafter, the details of embodiments of the present disclosure will be described with reference to the drawings. In the following drawings, the same or corresponding parts are denoted by the same reference numerals, and the description thereof will not be repeated.

### First Embodiment

A printed wiring board according to a first embodiment (referred to as “printed wiring board 100”) will be described.

### <Configuration of Printed Wiring Board 100>

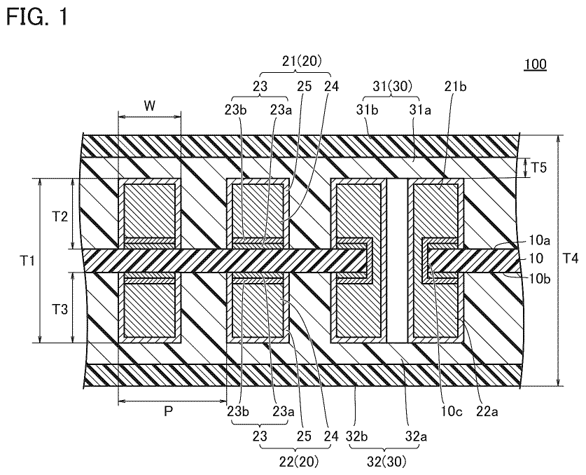

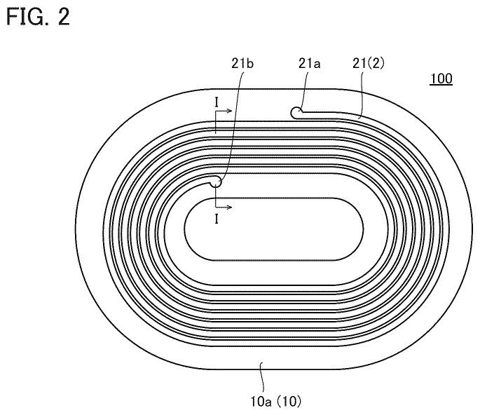

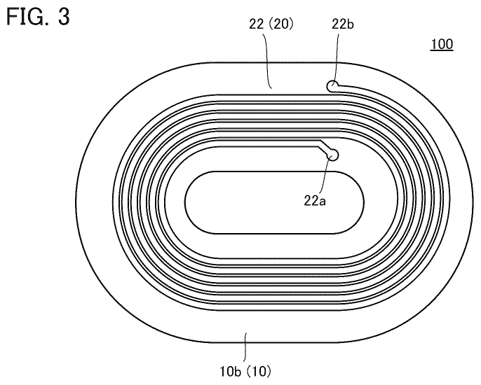

FIG. 1 is a cross-sectional view of a printed wiring board 100. FIG. 2 is a planar view of the printed wiring board 100. FIG. 3 is a bottom view of the printed wiring board 100. In FIGS. 2 and 3, a protective layer 30 is not illustrated. FIG. 3 illustrates the printed wiring board 100 viewed from the side opposite to FIG. 2. As illustrated in FIGS. 1 to 3, the printed wiring board 100 includes a base film 10, a coil wire 20, and a protective layer 30.

The base film 10 has a first main surface 10a and a second main surface 10b. The first main surface 10a and the second main surface 10b are end surfaces of the base film 10 in the thickness direction. The second main surface 10b is opposite to the first main surface 10a.

The base film 10 is made of a flexible electrically insulating material. The base film 10 is made of polyimide, polyethylene terephthalate, or fluororesin, for example.

A portion of the coil wire 20 on the first main surface 10a is defined as a first coil wire 21. A portion of the coil wire 20 on the second main surface 10b is defined as a second coil wire 22. The first coil wire 21 is formed in a spiral shape on the first main surface 10a. The second coil wire 22 is formed in a spiral shape on the second main surface 10b. The first coil wire 21 and the second coil wire 22 are electrically connected to each other. However, the coil wire 20 may not have either the first coil wire 21 or the second coil wire 22.

The coil wire 20 includes a seed layer 23, a first electrolytic plating layer 24, and a second electrolytic plating layer 25. The seed layer 23 is disposed on the main surface (the first main surface 10a, the second main surface 10b) of the base film 10. The first electrolytic plating layer 24 is disposed on the seed layer 23. The second electrolytic plating layer 25 covers the seed layer 23 and the first electrolytic plating layer 24. In other words, the second electrolytic plating layer 25 is disposed on the side surfaces of the seed layer 23 and on the side surfaces and the upper surface of the first electrolytic plating layer 24.

The seed layer 23 includes a first layer 23a and a second layer 23b. The first layer 23a is disposed on the main surface (the first main surface 10a, the second main surface 10b) of the base film 10. The second layer 23b is disposed on the first layer 23a. The first layer 23a is, for example, a sputtering layer (a layer formed by sputtering) made of a nickel-chromium alloy. The second layer 23b is, for example, an electroless plating layer (a layer formed by electroless plating) made of copper.

The first electrolytic plating layer 24 is, for example, an electrolytic plating layer (a layer formed by electrolytic plating) made of the same material (copper) as the second layer 23b. The second electrolytic plating layer 25 is an electrolytic plating layer made of copper, for example.

One end of the first coil wire 21 is formed as a land 21a. The other end of the first coil wire 21 is formed as a land 21b. One end of the second coil wire 22 is formed as a land 22a. The other end of the second coil wire 22 is formed as a land 22b. The land 21b and the land 22a overlap with each other in a planar view. The coil wire 20 (the first coil wire 21, the second coil wire 22) functions as a coil to generate a magnetic field when a current flows through the land 21a and the land 22b.

A through hole 10c is formed in the base film 10. The through hole 10c penetrates the base film 10 in the thickness direction. The through hole 10c overlaps with the land 21b and the land 22a in a planar view. The first coil wire 21 and the second coil wire 22 are electrically connected to each other by the second layer 23b, the first electrolytic plating layer 24, and the second electrolytic plating layer 25 which are formed on the inner wall surface of the through hole 10c.

The protective layer 30 disposed on the first main surface 10a is defined as a protective layer 31. The protective layer 30 disposed on the second main surface 10b is defined as a protective layer 32.

The protective layer 31 includes, for example, an adhesive layer 31a and a protective film 31b. The adhesive layer 31a is disposed on the first main surface 10a so as to cover the first coil wire 21. The protective film 31b is disposed on the adhesive layer 31a. The protective layer 32 includes, for example, an adhesive layer 32a and a protective film 32b. The adhesive layer 32a is disposed on the second main surface 10b so as to cover the second coil wire 22. The protective film 32b is disposed on the adhesive layer 32a.

The adhesive layer 31a and the adhesive layer 32a are formed of, for example, an epoxy adhesive. The protective film 31b and the protective film 32b are formed of, for example, polyimide. The protective layer 30 (the protective layer 31, the protective layer 32) may be a solder resist.

A width of the coil wire 20 is defined as a width W. A pitch between two adjacent portions of the coil wire 20 is defined as a pitch P. A thickness of the printed wiring board 100 excluding the protective layer 30 (the protective layer 31, the protective layer 32) is defined as a thickness T1. The thickness T1 is a distance between an upper surface of the first coil wire 21 and an upper surface of the second coil wire 22. The upper surface of the first coil wire 21 is a surface of the first coil wire 21 opposite to the base film 10, and the upper surface of the second coil wire 22 is a surface of the second coil wire 22 opposite to the base film 10. A thickness of the first coil wire 21 is defined as a thickness T2. A thickness of the second coil wire 22 is defined as a thickness T3.

A value obtained by dividing the width W by the pitch P is defined as a ratio R3, and a ratio of the sum of the thickness T2 and the thickness T3 to the thickness T1 (i.e., a value obtained by dividing the sum of the thickness T2 and the thickness T3 by the thickness T1) is defined as a ratio R4.

A value obtained by multiplying the ratio R3 by the ratio R4 is 0.35 or more and 0.85 or less. However, the value obtained by multiplying the ratio R3 by the ratio R4 is not required to be 0.35 or more and 0.85 or less in all portions of the printed wiring board 100. It is acceptable that the value obtained by multiplying the ratio R3 by the ratio R4 is 0.35 or more and 0.85 or less in some portions of the printed wiring board 100.

A thickness of the printed wiring board 100 is referred to as a thickness T4. A ratio of the sum of the thickness T2 and the thickness T3 to the thickness T4 (i.e., a value obtained by dividing the sum of the thickness T2 and the thickness T3 by the thickness T4) is defined as a ratio R5.

A value obtained by multiplying the ratio R3 by the ratio R5 is 0.30 or more and 0.90 or less. It is preferable that the value obtained by multiplying the ratio R3 by the ratio R5 is 0.40 or more and 0.65 or less. However, the value obtained by multiplying the ratio R3 by the ratio R5 is not required to be 0.30 or more and 0.90 or less (or 0.40 or more and 0.65 or less) in all portions of the printed wiring board 100. It is acceptable that the value obtained by multiplying the ratio R3 by the ratio R5 is 0.30 or more and 0.90 or less (or 0.40 or more and 0.65 or less) in some portions of the printed wiring board 100.

The ratio R3 is, for example, 0.72 or more and 0.93 or less. It is acceptable that the coil wire 20 (the first coil wire 21, the second coil wire 22) has a portion where the ratio R3 is 0.72 or more and 0.93 or less. Each of the thickness T2 and the thickness T3 is, for example, 40 μm or more and 60 μm or less. It is acceptable that the first coil wire 21 has a portion where the thickness T2 thereof is 40 μm or more and 60 μm or less, and the second coil wire 22 has a portion where the thickness T3 thereof is 40 μm or more and 60 μm or less.

The width W is, for example, 20 μm or more and 40 μm or less. It is acceptable that the coil wire 20 (the first coil wire 21 and the second coil wire 22) has a portion where the width W thereof is 20 μm or more and 40 μm or less. A width of the adhesive layer 31a (the adhesive layer 32a) is defined as a thickness T5. The thickness T5 is a distance between the upper surface of the first coil wire 21 (the second coil wire 22) and the protective film 31b (the protective film 32b). The thickness T5 is preferably 10 μm or more and 25 μm or less.

### Method of Manufacturing Printed Wiring Board 100

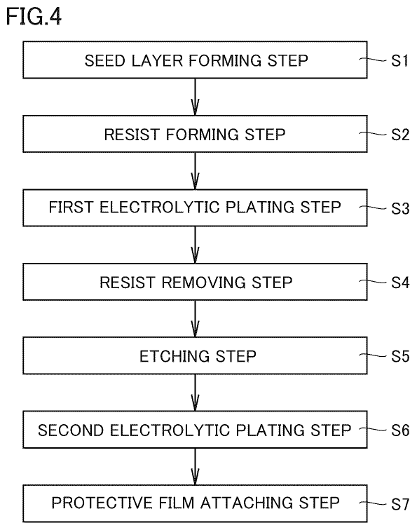

FIG. 4 is a process chart illustrating a method of manufacturing the printed wiring board 100. As illustrated in FIG. 4, the method of manufacturing the printed wiring board 100 includes a seed layer forming step S1, a resist forming step S2, a first electrolytic plating step S3, a resist removing step S4, an etching step S5, a second electrolytic plating step S6, and a protective film attaching step S7.

The resist forming step S2 is performed after the seed layer forming step S1. The first electrolytic plating step S3 is performed after the resist forming step S2. The resist removing step S4 is performed after the first electrolytic plating step S3. The etching step S5 is performed after the resist removing step S4. The second electrolytic plating step S6 is performed after the etching step S5. The protective film attaching step S7 is performed after the second electrolytic plating step S6.

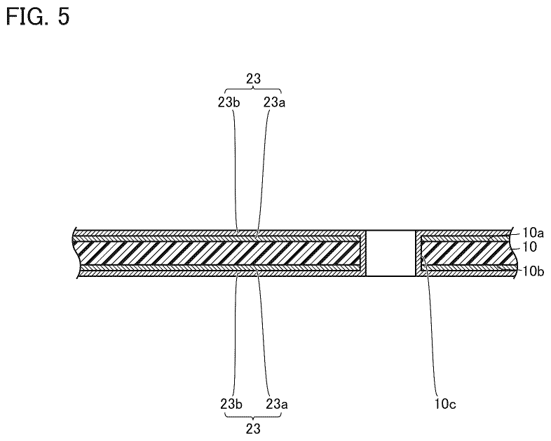

FIG. 5 is a cross-sectional view illustrating the seed layer forming step S1. As illustrated in FIG. 5, in the seed layer forming step S1, the seed layer 23 is formed. Firstly, in the seed layer forming step S1, the first layer 23a is formed on the main surface (the first main surface 10a, the second main surface 10b) of the base film 10. The first layer 23a is formed by sputtering, for example.

Secondly, the through hole 10c is formed in the seed layer forming step S1. The through hole 10c is formed, for example, by irradiating the base film 10 with a laser beam. Thirdly, in the seed layer forming step S1, the second layer 23b is formed on the first layer 23a. The second layer 23b is also formed on the inner wall surface of the through hole 10c. The second layer 23b is formed by, for example, electroless plating.

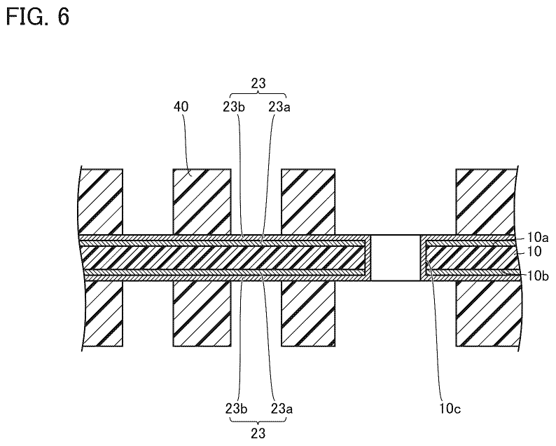

FIG. 6 is a cross-sectional view illustrating the resist forming step S2. As illustrated in FIG. 6, in the resist forming step S2, a resist 40 is formed on the seed layer 23. The resist 40 is formed, for example, by attaching a dry film resist on the seed layer 23, and patterning the attached dry film resist by exposing and developing the attached dry film resist.

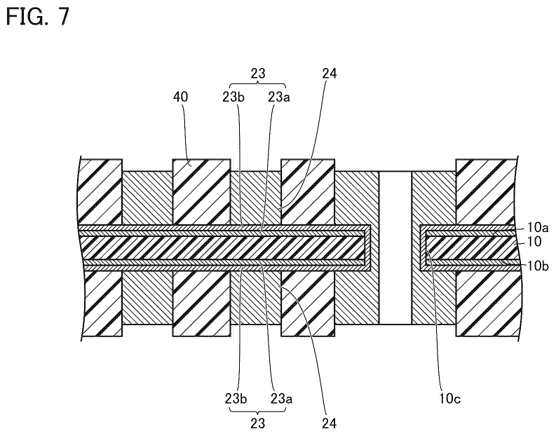

FIG. 7 is a cross-sectional view illustrating the first electrolytic plating step S3. As illustrated in FIG. 7, in the first electrolytic plating step S3, the first electrolytic plating layer 24 is formed on the seed layer 23 exposed from the resist 40. The first electrolytic plating layer 24 is also formed on the second layer 23b on the inner wall surface of the through hole 10c. The first electrolytic plating layer 24 is formed by applying an electric current to the seed layer 23 in a plating solution containing a material constituting the first electrolytic plating layer 24.

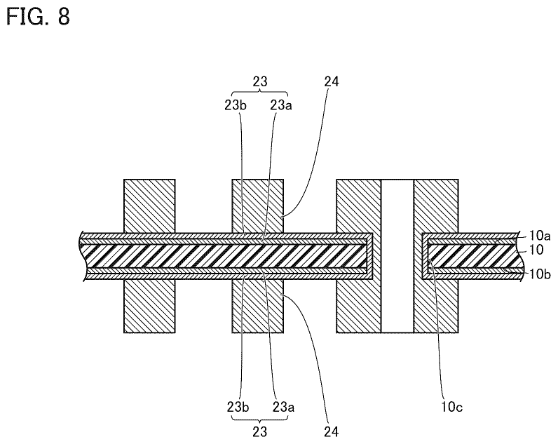

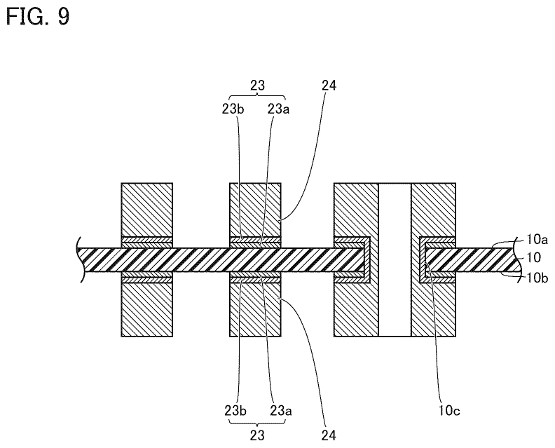

FIG. 8 is a cross-sectional view illustrating the resist removing step S4. As illustrated in FIG. 8, the resist 40 is removed in the resist removing step S4. FIG. 9 is a cross-sectional view illustrating the etching step S5. As illustrated in FIG. 9, in the etching step S5, the seed layer 23 exposed between two adjacent portions of the first electrolytic plating layer 24 is removed by etching.

Firstly, the second layer 23b is etched in the etching step S5. The second layer 23b is etched by supplying an etching solution between two adjacent portions of the first electrolytic plating layer 24. The etching solution is selected in such a manner that the etching rate is controlled by a reaction between reactive species in the etching solution and an etching target, rather than by the diffusion of the reactive species in the etching solution to the vicinity of the etching target.

More specifically, an etching solution having a dissolution reaction rate of 1.0 μm/min or more with respect to the material (i.e., copper) constituting the second layer 23b is used as the etching solution. Specific examples of the etching solution include a sulfuric acid/hydrogen peroxide aqueous solution or a sodium peroxodisulfate aqueous solution. The dissolution reaction rate of the etching solution is measured based on a weight of copper decreased after etching and an etching time.

Secondly, the first layer 23a is etched in the etching step S5. An alternative etching solution is used to etch the first layer 23a. As the alternative etching solution, an etching solution having a high selectivity to the material (i.e., nickel-chromium alloy) constituting the first layer 23a is used. Therefore, the first electrolytic plating layer 24 is difficult to be etched in the alternative etching solution.

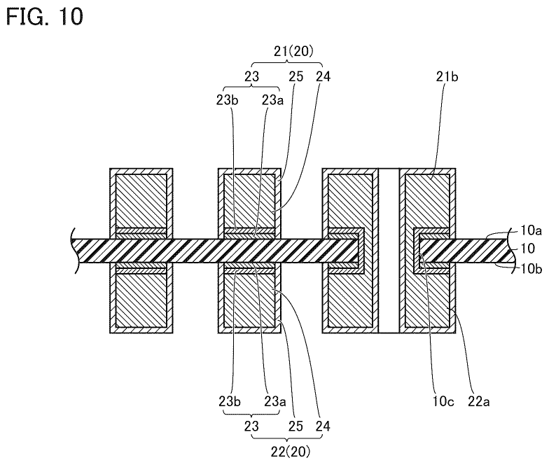

FIG. 10 is a cross-sectional view illustrating the second electrolytic plating step S6. As illustrated in FIG. 10, in the second electrolytic plating step S6, the second electrolytic plating layer 25 is formed so as to cover the seed layer 23 and the first electrolytic plating layer 24. The second electrolytic plating layer 25 is also formed on the first electrolytic plating layer 24 which is formed on the inner wall surface of the through hole 10c with the second layer 23b interposed therebetween.

The second electrolytic plating layer 25 is formed by applying an electric current to the seed layer 23 and the first electrolytic plating layer 24 in the plating solution containing the material constituting the second electrolytic plating layer 25. Thus, the coil wire 20 (the first coil wire 21, the second coil wire 22) is formed using a semi-additive process.

The protective layer 30 is formed in the protective film attaching step S7. Firstly, in the protective film attaching step S7, the protective film 31b coated with the adhesive layer 31a is disposed on the first main surface 10a so as to cover the first coil wire 21, and the protective film 32b coated with the adhesive layer 32a is disposed on the second main surface 10b so as to cover the second coil wire 22. At this time, the adhesive layer 31a and the adhesive layer 32a are not cured.

Secondly, in the protective film attaching step S7, the protective film 31b and the protective film 32b are pressed against the base film 10 while being heated. Thus, the adhesive layer 31a and the adhesive layer 32a are cured, and the protective film 31b and the protective film 32b are attached to the base film 10. Thus, the printed wiring board 100 having the structure illustrated in FIG. 1 is manufactured.

### <Effect of Printed Wiring Board 100>

Conventionally, an etching solution having a greater dissolution reaction rate with respect to a material constituting a seed layer (i.e., the etching rate of the etching solution is controlled by the diffusion of reactive species in the etching solution to the vicinity of the etching target) has been used. If the distance between two adjacent portions of a coil wire is shorter, it is difficult for the etching solution to be supplied between two adjacent portions of the coil wire. In addition, when the thickness of the coil wire is greater, it is difficult for the etching solution to be supplied between two adjacent portions of the coil wire.

As a result, when the etching solution described above is used, the etching of the seed layer becomes significantly irregular, which increases the etching amount to reliably remove the seed layer. Due to the reasons mentioned above, conventionally, it is impossible to shorten the distance between two adjacent portions of the coil wire, and it is impossible to increase the thickness of the coil wire.

In the printed wiring board 100, in the etching step S5, an etching solution having a smaller dissolution reaction rate with respect to the material constituting the second layer 23b is used. As a result, the etching rate of the etching step S5 is controlled by the reaction between the reactive species in the etching solution and the etching target, and even if the etching solution is difficult to be supplied between the two adjacent portions of the first electrolytic plating layer 24, the etching of the second layer 23b is less likely to become irregular.

Therefore, the pattern density and thickness of the coil wire 20, in other words, the ratio R3 and the ratio R4 (ratio R5) can be made greater in the printed wiring board 100. As a result, when the printed wiring board 100 is used in a coil device, it is possible to improve the thrust while preventing the electrical resistance from increasing.

### Second Embodiment

A coil device according to a second embodiment (referred to as “coil device 200”) will be described.

### <Configuration of Coil Device 200>

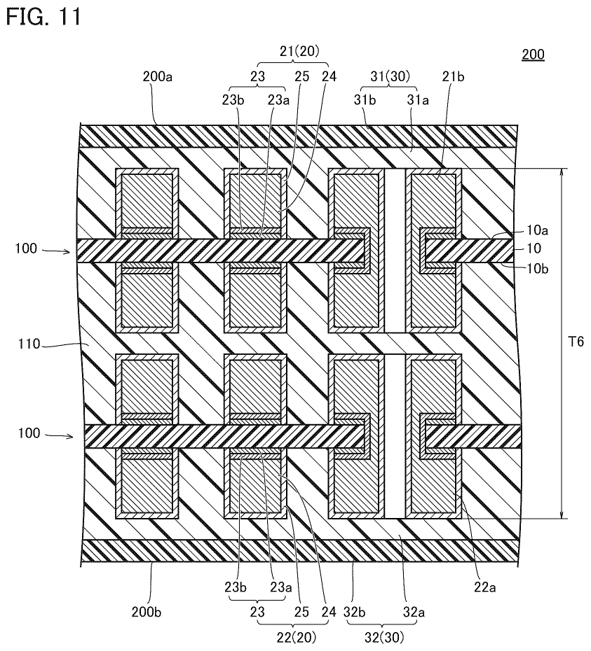

FIG. 11 is a cross-sectional view of a coil device 200. As illustrated in FIG. 11, the coil device 200 includes a first surface 200a and a second surface 200b. The second surface 200b is a surface opposite to the first surface 200a. The first surface 200a and the second surface 200b are end surfaces in the thickness direction of the coil device 200.

The coil device 200 includes a plurality of printed wiring boards 100 and an adhesive layer 110. The plurality of printed wiring boards 100 are stacked in the thickness direction of the coil device 200. The adhesive layer 110 is disposed between two of the printed wiring boards 100 adjacent to each other in the thickness direction of the coil device 200. As described above, in each of the plurality of printed wiring boards 100, the coil wire 20 may be formed on at least one of the first main surface 10a and the second main surface 10b.

The protective layer 31 is only disposed on the first main surface 10a of the printed wiring board 100 which is closest to the first surface 200a, and the protective layer 32 is only disposed on the second main surface 10b of the printed wiring board 100 which is closest to the second surface 200b.

The thickness of the coil device 200 is defined as a thickness T6. The thickness T6 is the sum of the thickness of the adhesive layer 110 (the sum of the thicknesses of the adhesive layers 110 when the number of the adhesive layers 110 is plural) and the sum of the thickness of the coil wire 20 and the thickness of the base film 10 for the plurality of printed wiring boards 100. The average value of the ratios R3 for the plurality of printed wiring boards 100 is defined as a ratio R1. A value obtained by summing a value obtained by dividing the thickness of the coil wire 20 by the thickness T6 for the plurality of printed wiring boards is defined as a ratio R2.

The value obtained by multiplying the ratio R1 by the ratio R2 is 0.35 or more and 0.85 or less. The value obtained by multiplying the ratio R1 by the ratio R2 is not required to be 0.35 or more and 0.85 or less in all portions of the printed wiring board 100. It is acceptable that the value obtained by multiplying the ratio R1 by the ratio R2 is 0.35 or more and 0.85 or less in some portions of the printed wiring board 100. It is preferable that the coil device 200 has a portion where the value obtained by multiplying the ratio R1 by the ratio R2 is 0.38 or more. It is more preferable for it to have a portion where the value obtained by multiplying the ratio R1 by the ratio R2 is 0.49 or more.

### <Effect of Coil Device 200>

In the coil device 200, since the pattern density and thickness of the coil wire 20, i.e., the ratio R1 and the ratio R2, can be made greater, it is possible to improve the thrust while preventing the electrical resistance from increasing.

### EXAMPLES

In order to confirm the effect of the coil device 200, samples 1 to 12 were prepared. In samples 1 to 12, the value obtained by multiplying the ratio R1 by the ratio R2, the electrical resistance, and the thickness T6 were different. The details of samples 1 to 12 are listed in Table 1.

TABLE 1

| | | | | | Inductance ÷ |
|---|---|---|---|---|---|
| | | | Electric | | (T6 × Electric |
| | | T6 | Resistance | Inductance | Resistance) |
| Sample | R1 × R2 | (μm) | (Ω) | (μH) | (μH/(μm · Ω)) |
| 1 | 0.279 | 369 | 17.56 | 7.58 | 0.0012 |
| 2 | 0.382 | 276 | 13.27 | 11.89 | 0.0032 |
| 3 | 0.504 | 139 | 10.42 | 12.61 | 0.0087 |
| 4 | 0.532 | 208 | 12.60 | 17.25 | 0.0066 |
| 5 | 0.570 | 208 | 14.11 | 23.18 | 0.0079 |
| 6 | 0.592 | 208 | 12.10 | 22.58 | 0.0090 |
| 7 | 0.629 | 108 | 10.92 | 8.16 | 0.0069 |
| 8 | 0.633 | 108 | 10.50 | 7.41 | 0.0066 |
| 9 | 0.633 | 108 | 10.50 | 6.88 | 0.0061 |
| 10 | 0.657 | 108 | 10.50 | 6.97 | 0.0062 |
| 11 | 0.665 | 108 | 10.50 | 6.97 | 0.0062 |
| 12 | 0.681 | 108 | 10.49 | 9.27 | 0.0082 |

The performance of each sample, i.e., each coil device, was evaluated according to the value obtained by dividing the inductance of each sample by the product of the electrical resistance and the thickness T6 of each sample. Since the inductance of a coil device is substantially proportional to the thrust of the coil device, the inductance is used as an indicator of the thrust generated by the coil device. As the thickness of the coil device increases, the electrical resistance and the thrust of the coil device tend to increase. Therefore, the larger the value obtained by dividing the inductance of the coil device by the product of the thrust and the electrical resistance of the coil device is, the higher the thrust is while preventing the electrical resistance from increasing.

A measuring device used to measure the electrical resistance and the inductance of each sample includes a first probe and a second probe. The first probe and the second probe are brought into contact with one end and the other end of the coil circuit of each sample, respectively. When an AC voltage of 100 mV and 100 kHz is applied between the first probe and the second probe, the measuring device measures a current flowing through the coil circuit of each sample, and calculates an electrical resistance and an inductance of each sample based on the measured current.

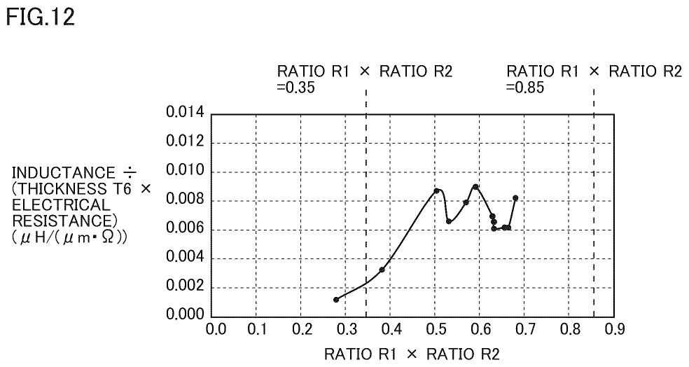

FIG. 12 is a graph illustrating a relationship between a value obtained by multiplying the ratio R1 by the ratio R2 and the performance of each sample. In FIG. 12, the horizontal axis represents a value obtained by multiplying the ratio R1 by the ratio R2. In FIG. 12, the vertical axis represents a value (unit: μH/(μm·Ω)) obtained by dividing the inductance of each sample by the product of the thickness T6 and the electrical resistance of each sample.

As illustrated in FIG. 12, for samples 2 to 12, the value obtained by multiplying the ratio R1 by the ratio R2 was in the range of 0.35 or more and 0.85 or less. On the other hand, for sample 1, the value obtained by multiplying the ratio R1 by the ratio R2 was less than 0.35. For samples 2 to 12, the value obtained by dividing the inductance by the product of the thickness T6 and the electrical resistance was 0.002 pH/(μm·Ω) or more. On the other hand, for sample 1, the value obtained by dividing the inductance by the product of the thickness T6 and the electrical resistance was less than 0.002 μH/(μm·Ω). Therefore, it is apparent that by setting the value obtained by multiplying the ratio R1 by the ratio R2 in the range of 0.35 or more and 0.85 or less, it is possible to increase the thrust of the coil device 200 while preventing the electrical resistance of the coil device 200 from increasing.

As illustrated in FIG. 12, as the value obtained by multiplying the ratio R1 by the ratio R2 becomes equal to or greater than 0.35, the value obtained by dividing the inductance by the product of the thickness T6 and the electrical resistance increases rapidly. Thus, it is apparent that by setting the value obtained by multiplying the ratio R1 by the ratio R2 to 0.35 or more, it is possible to particularly increase the thrust of the coil device 200 while preventing the electrical resistance of the coil device 200 from increasing.

It should be understood that the embodiments disclosed herein are illustrative and non-restrictive in every respect. The scope of the present invention is defined by the scope of the claims, rather than the embodiments described above, and is intended to include any modifications within the scope and meaning equivalent to the scope of the claims.

### REFERENCE SIGNS LIST

10: base film; 10a: first main surface; 10b: second main surface; 10c: through hole; 20: coil wire; 21: first coil wire; 21a: land; 21b: land; 22: second coil wire; 22a: land; 22b: land; 23: seed layer; 23a: first layer; 23b: second layer; 24: first electrolytic plating layer; 25: second electrolytic plating layer; 30: adhesive layer; 31: protective layer; 31a: adhesive layer; 31b: protective film; 32: protective layer; 32a: adhesive layer; 32b: protective film; 40: resist; 100: printed wiring board; 110: adhesive layer; 200: coil device; 200a: first surface; 200b: second surface; T1, T2, T3, T4, T5, T6: thickness; W: width; P: pitch; R1, R2, R3, R4, R5: ratio; S1: seed layer forming step; S2: resist forming step; S3: first electrolytic plating step; S4: resist removing step; S5: etching step; S6: second electrolytic plating step; S7: protective film attaching step

1. A coil device comprising:
a plurality of printed wiring boards; and
an adhesive layer,
wherein the plurality of printed wiring boards are stacked in a thickness direction of the coil device,
each of the plurality of printed wiring boards includes a base film having a first main surface and a second main surface, and a coil wire formed in a spiral shape on at least one of the first main surface and the second main surface,
the adhesive layer is disposed between the plurality of printed wiring boards adjacent to each other in the thickness direction of the coil device,
a thickness of the coil device is a sum of a thickness of the adhesive layer and a sum of a thickness of the coil wire and a thickness of the base film for the plurality of printed wiring boards,
the coil device has a portion that satisfies expression (1),
$$0.35 \leq R 1 \times R 2 \leq 0.85 \qquad Expression ( 1 )$$
wherein R1 is obtained by averaging a value obtained by dividing a width of the coil wire by a pitch between two adjacent portions of the coil wire for the plurality of printed wiring boards, and R2 is obtained by summing a value obtained by dividing the thickness of the coil wire by the thickness of the coil device for the plurality of printed wiring boards.

2. A printed wiring board comprising:
a base film having a first main surface and a second main surface; and
a coil wire formed in a spiral shape on the first main surface and the second main surface,
wherein the printed wiring board has a portion that satisfies expression (2),
0.35≤R3×R4≤0.85 Expression (2)
wherein R3 is obtained by dividing a width of the coil wire by a pitch between two adjacent portions of the coil wire, and R4 is a ratio of a thickness of the coil wire on the first main surface and the second main surface to a distance between an upper surface of the coil wire on the first main surface and an upper surface of the coil wire on the second main surface.

3. A printed wiring board comprising:
a base film having a first main surface and a second main surface;
a coil wire formed in a spiral shape on the first main surface and the second main surface; and
a protective layer disposed on the first main surface and the second main surface so as to cover the coil wire,
wherein the printed wiring board has a portion that satisfies expression (3),
0.30≤R3×R5≤0.90 Expression (3)
wherein R3 is obtained by dividing a width of the coil wire by a pitch between two adjacent portions of the coil wire, and R5 is a ratio of a thickness of the coil wire on the first main surface and the second main surface to a thickness of the printed wiring board.

4. The printed wiring board according to claim 3, wherein
the printed wiring board has a portion that satisfies expression (4).
$$0.40 \leq R 3 \times R 5 \leq 0.65 \qquad Expression ( 4 )$$

5. The printed wiring board according to claim 3, wherein
the protective layer includes an adhesive layer covering the coil wire, and
a thickness of the adhesive layer is 10 μm or more and 25 μm or less.

6. The printed wiring board according to claim 2, wherein
the coil wire has a portion that satisfies expression (5),
$$0.72 \leq W \div P \leq 0.93 \qquad Expression ( 5 )$$
wherein W is a width of the coil wire, and P is a pitch between two adjacent portions of the coil wire.

7. The printed wiring board according to claim 2, wherein
the coil wire has a portion where the thickness thereof is 40 μm or more and 60 μm or less.

8. The printed wiring board according to claim 2, wherein
the coil wire has a portion where the width thereof is 20 μm or more and 40 μm or less.
